(19) United States
(12) Patent Application Publication
(10) Pub. No.: US 2017/0358585 A1
(43) Pub. Date: Dec. 14, 2017

(54) METHOD, APPARATUS AND SYSTEM FOR FABRICATING SELF-ALIGNED CONTACT USING BLOCK-TYPE HARD MASK

(71) Applicant: GLOBALFOUNDRIES Inc., Grand Cayman (KY)

(72) Inventors: Kwanyong Lim, Nishakuna, NY (US); Ryan Ryoung-han Kim, Albany, NY (US); Ruilong Xie, Nishakuna, NY (US)

(73) Assignee: GLOBALFOUNDRIES INC., GRAND CAYMAN (KY)

(21) Appl. No.: 15/182,487

(22) Filed: Jun. 14, 2016

(51) Int. Cl. H01L 27/11; H01L 21/02; H01L 21/28; H01L 21/3105; H01L 21/768; H01L 21/311; H01L 29/40; H01L 21/321

(52) U.S. Cl. CPC H01L 27/1104; H01L 29/401; H01L 21/02164; H01L 21/0217; H01L 21/3212; H01L 21/31053; H01L 21/76897; H01L 21/31144; H01L 21/28017; H01L 21/31116

(57) ABSTRACT

At least one method, apparatus and system disclosed herein involves processing a semiconductor wafer using block mask design for manufacturing a finFET device. The gate structure comprising a source structure, and a drain structure of a transistor is formed. The gate structure is surrounded by an inter-layer dielectric (ILD) region. A 1st and a 2nd hard mask (HM) layer is formed above the gate structure and the ILD region. A 1st and 2nd block mask of a 1st and 2nd color are respectively formed. The 1st and 2nd HM layers are selectively etched based on the 1st and 2nd block mask layers for forming spaces for metal deposition. A contact metal deposition process is performed for forming a plurality of contact metal features. The 1st and 2nd HM layers are removed. A 3rd etch process is performed for etching back the contact metal features to form contact metal structures.

### BACKGROUND OF THE INVENTION

### FIELD OF THE INVENTION

Generally, the present disclosure relates to the manufacture of sophisticated semiconductor devices, and more specifically, to various methods for fabricating finFET devices having self aligned contact using block type hard mask.

### DESCRIPTION OF THE RELATED ART

The fabrication of advanced integrated circuits, such as CPU's, storage devices, ASIC's (application specific integrated circuits) and the like, requires the formation of a large number of circuit elements in a given chip area according to a specified circuit layout, wherein so-called metal oxide field effect transistors (MOSFETs or FETs) represent one important type of circuit element that substantially determines performance of the integrated circuits. A FET is a device that typically includes a source region, a drain region, a channel region that is positioned between the source region and the drain region, and a gate electrode positioned above the channel region. Current flow through the FET is controlled by controlling the voltage applied to the gate electrode. If a voltage that is less than the threshold voltage of the device is applied to the gate electrode, then there is no current flow through the device (ignoring undesirable leakage currents, which are relatively small). However, when a voltage that is equal to or greater than the threshold voltage of the device is applied to the gate electrode, the channel region becomes conductive, and electrical current is permitted to flow between the source region and the drain region through the conductive channel region.

To improve the operating speed of FETs, and to increase the density of FETs on an integrated circuit device, device designers have greatly reduced the physical size of FETs over the years. More specifically, the channel length of FETs has been significantly decreased, which has resulted in improving the switching speed of FETs. However, decreasing the channel length of a FET also decreases the distance between the source region and the drain region. In some cases, this decrease in the separation between the source and the drain makes it difficult to efficiently inhibit the electrical potential of the channel from being adversely affected by the electrical potential of the drain. This is sometimes referred to as a so-called short channel effect, wherein the characteristic of the FET as an active switch is degraded.

In contrast to a planar FET, which has a planar structure, there are so-called 3D devices, such as an illustrative finFET device, which is a 3-dimensional structure. More specifically, in a finFET, a generally vertically positioned, fin-shaped active area is formed and a gate electrode encloses both of the sides and the upper surface of the fin-shaped active area to form a trigate structure so as to use a channel having a 3-dimensional structure instead of a planar structure. In some cases, an insulating cap layer, e.g., silicon nitride, is positioned at the top of the fin and the finFET device only has a dual-gate structure.

FinFET designs use “fins” that may be formed on the surface of a semiconductor wafer using selective-etching processes. The fins may be used to form a raised channel between the gate and the source and drain of a transistor. The gate is then deposited such that it wraps around the fin to form a trigate structure. Since the channel is extremely thin, the gate would generally have a greater control over the carriers within. However, when the transistor is switched on, the shape of the channel may limit the current flow. Therefore, multiple fins may be used in parallel to provide greater current flow for increased drive strength.

FIG. 1 illustrates a stylized cross-sectional depiction of a state-of-the-art finFET device. A finFET device 100 illustrated in FIG. 1 comprises a plurality of “fins” 110. The semiconductor device may be position to a vertical orientation, creating one or more fins 110. The source and drain of the finFET are placed horizontally along the fin. A high-k metal gate 120 wraps over the fin, covering it on three sides. The gate 120 defines the length of the finFET device. The current flow occurs along an orthogonal crystal plane in a direction parallel to the plane of the semiconductor wafer. The electrically significant height of the fin (labeled H) is typically determined by the amount of oxide recess in the fin reveal step and hence is constant for all fins 110.

The thickness of the fin (labeled T_{fi}) determines the short channel behavior of the transistor device and is usually small in comparison with the height H of the fin 110. The pitch (labeled P) of the fins is determined by lithographic constraints and dictates the wafer area to implement the desired device width. A small value of the pitch P and a large value of the height H enable a better packing of the devices per square area resulting in a denser design, or more efficient use of silicon wafer area.

The scaling down of integrated circuits coupled with higher performance requirements for these circuits have prompted an increased interest in finFETs. FinFETs generally have the increased channel widths, which includes channel portions formed on the sidewalls and top portions of the fins. Since drive currents of the finFETs are proportional to the channel widths, finFETs generally display increase drive current capabilities.

Designers often use pre-designed basic cells to form layouts of more complex cells comprising finFET devices. For example, designers often use a unit SRAM cell to design and fabricate a memory device. In a CMOS integrated circuit, PMOS and NMOS transistor pairing are often used to form circuit cells.

For example, FIG. 2 illustrates a stylized cross-sectional depiction of a state-of-the-art memory device design. FIG. 2 depicts a CMOS finFET device 200, which comprises a PMOS portion 201 and a complimentary NMOS portion 202 formed on a substrate 203. The device 200 comprises a plurality of gate formations 210 and a plurality of source/drain (S/D) formations 220. In this manner, a plurality of gate and S/D formations 210, 220 may be formed to provide a plurality of NMOS and PMOS transistor devices to form an integrated circuit, e.g., a memory device. A rectangle in FIG. 2 denotes a collection of structures that are interconnected to form an SRAM memory cell 260.

In order to form various features for providing a memory device, a plurality of different “color” masks may be used to perform process operations. In multiple-patterning processes, the metal features that are formed are typically referred to as either “mandrel-metal” features (“MM”) or “non-mandrel-metal” features (“NMM”). As it relates to terminology, the MM features and NMM features are referred to as being different “colors” when it comes to decomposing an overall pattern layout that is intended to be manufactured using a double-patterning process. Thus, two MM features are said to be of the “same color” and two NMM features are said to be of the “same color, while an MM feature and an NMM feature are said to be of “different colors.” In some cases different photoresist masks used to respectively different lithography processes may each refer to a different color.

To use multiple patterning techniques, an overall pattern layout for a circuit must be what is referred to as multi-patterning compliant. Multi-patterning compliant generally refers to an overall pattern layout being decomposed into two separate patterns, such that each may be formed using existing photolithography tools and other techniques. One well-known multi-patterning technique is referred to as LELE (“litho-etch-litho-etch) double patterning. As the name implies, the LELE process involves forming two photoresist etch masks and performing two etching processes to transfer the desired overall pattern to a hard mask layer that is then used as an etch mask to etch an underlying layer of material. With respect to terminology, the different masks employed in the LELE double patterning process are said to be different “colors.” Thus, depending upon the spacing between adjacent features, the features may be formed using the same photoresist mask (“same color”) or they may have to be formed using different photoresist masks (“different color”). In an LELE process, if two adjacent features are spaced apart by a distance that can be patterned using traditional single exposure photolithography, then those two adjacent features may be formed using the same (“same color”) photoresist mask. In contrast, if the spacing between the two adjacent features is less than can be formed using single exposure photolithography, then those features must be either formed using different photoresist masks (“different color”) or the spacing between the features must be increased by changing the circuit layout such that they may be formed using the same photoresist mask.

Continuing referring to FIG. 2, in order to fabricate a memory device, state-of-the-art techniques call for using three S/D contact color masks and two cross-coupled contact color masks. Thus, a total of five color masks may be used by be used to fabricate the integrated circuit shown in FIG. 2.

In order to fabricate S/D contact formations in the integrated circuit 200 of FIG. 2, a 1^{st} S/D contact mask 242a, 242b (collectively “242”), a 2^{nd} S/D contact mask 240a, 240b, 240c (collectively “240”), and a 3^{rd} S/D mask 250a, 250b, 250c (collectively “250”). The 1^{st}, 2^{nd} and 3^{rd} masks 242, 240, 250 are used at separate processing steps and represent three different color masks. The 1^{st}, 2^{nd} and 3^{rd} masks 242, 240, 250 are used to form source and drain formations in the circuit 200.

In order to create connections between the source and drain features of the circuit 200, cross-coupled contact masks of different colors may be used. A 1^{st} cross-coupled contact mask 252a, 252b (collectively “252”) and a 2^{nd} cross-coupled 254a, 254b (collectively “254”) may be used to form connection between source and drain features.

However, there are problems associated with this state-of-the-art approach. The structures formed from using the masks are generally densely arranged, particularly as device become smaller. Therefore, if there are any mask shifts during processing, contact bridges may form, leading to shorts and other circuit errors. For example, as a result of overlay and/or critical dimension (CD) shift, the space between two different color masks 250b (3^{rd} contact mask) and 240a (1^{st} contact mask) may become too small, resulting in a significant contact bridge. Similar errors could occur near other color masks as a result of overlay and/or CD shift (e.g., a contact bridge between the color masks 240c (2^{nd} contact mask) and 254a (2^{nd} cross-coupled mask). This causes low tip-to-tip margins. Therefore, using state-of-the-art processing, even slight overlay and/or CD shifts can cause process problems and device operation problems, which may result in a lower yield.

The present disclosure may address and/or at least reduce one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to various methods, apparatus and system for for processing a semiconductor wafer using block mask design for manufacturing a finFET device. A gate structure is formed. The gate structure comprises a source structure, and a drain structure of a transistor. The gate structure is surrounded by an inter-layer dielectric (ILD) region. A a first hard mask layer is formed above the gate structure and the ILD region. A second hard mask layer is formed above the first hard mask layer. A first block mask of a first color is formed. A second block mask of a second color is formed. The first and second hard mask layers are selectively etched based on the first and second block mask layers for forming spaces for metal deposition. A contact metal deposition process is performed for forming a plurality of contact metal features. The first and second hard mask layers are removed. A third etch process is performed for etching back the contact metal features to form contact metal structures.

### BRIEF DESCRIPTION OF THE DRAWINGS

The disclosure may be understood by reference to the following description taken in conjunction with the accompanying drawings, in which like reference numerals identify like elements, and in which:

FIG. 1 illustrates a stylized cross-sectional depiction of a state-of-the-art finFET device;

FIG. 2 illustrates a stylized depiction of a stylized cross-sectional depiction of a state-of-the-art memory device design;

FIGS. 3A-3D illustrate stylized depictions of various cross-sectional views of an integrated circuit with regard to post fin, PC and S/D formation processes, in accordance with embodiments herein;

FIGS. 4A-4D illustrate stylized depictions of various cross-sectional views of an integrated circuit with regard to an ILD deposition process, in accordance with embodiments herein;

FIGS. 5A-5D illustrate stylized depictions of various cross-sectional views of an integrated circuit with regard to ILD CMP/Poly Open CMP processes, in accordance with embodiments herein;

FIGS. 6A-6D illustrate stylized depictions of various cross-sectional views of an integrated circuit with regard to mask deposition and PC cut mask processes, in accordance with embodiments herein;

FIGS. 7A-7D illustrate stylized depictions of various cross-sectional views of an integrated circuit with regard to a PC cut RIE processes, in accordance with embodiments herein;

FIGS. 8A-8D illustrate stylized depictions of various cross-sectional views of an integrated circuit with regard to a PC cut nitride deposition process, in accordance with embodiments herein;

FIGS. 9A-9D illustrate stylized depictions of various cross-sectional views of an integrated circuit with regard to a PC cut nitride CMP process, in accordance with embodiments herein;

FIGS. 10A-10D illustrate stylized depictions of various cross-sectional views of an integrated circuit with regard to a poly pull process, in accordance with embodiments herein;

FIGS. 11A-11D illustrate stylized depictions of various cross-sectional views of an integrated circuit with regard to a RMG metal process, in accordance with embodiments herein;

FIGS. 12A-12D illustrate stylized depictions of various cross-sectional views of an integrated circuit with regard to a RMG metal recess process, in accordance with embodiments herein;

FIGS. 13A-13D illustrate stylized depictions of various cross-sectional views of an integrated circuit with regard to a RMG metal recess process, in accordance with embodiments herein;

FIGS. 14A-14D illustrate stylized depictions of various cross-sectional views of an integrated circuit with regard to a RMG SAC nitridce CMP process, in accordance with embodiments herein;

FIGS. 15A-15G illustrate stylized depictions of various cross-sectional views of an integrated circuit with regard to a SAC hard mask (HM) process, in accordance with embodiments herein;

FIGS. 16A-16D illustrate stylized depictions of various cross-sectional views of an integrated circuit with regard to a SAC block type mask process, in accordance with embodiments herein;

FIGS. 17A-17D illustrate stylized depictions of various cross-sectional views of an integrated circuit with regard to a SAC HM RIE process, in accordance with embodiments herein;

FIGS. 18A-18D illustrate stylized depictions of various cross-sectional views of an integrated circuit with regard to a SAC RIE process, in accordance with embodiments herein;

FIGS. 19A-19D illustrate stylized depictions of various cross-sectional views of an integrated circuit with regard to a contact metal deposition process, in accordance with embodiments herein;

FIGS. 20A-20D illustrate stylized depictions of various cross-sectional views of an integrated circuit with regard to a contact metal CMP process, in accordance with embodiments herein;

FIGS. 21A-21D illustrate stylized depictions of various cross-sectional views of an integrated circuit with regard to a selective SAC HM removal process, in accordance with embodiments herein;

FIGS. 22A-22D illustrate stylized depictions of various cross-sectional views of an integrated circuit with regard to a contact metal etch-back process, in accordance with embodiments herein; and

FIG. 23 illustrates a stylized depiction of a system for fabricating a semiconductor device package comprising a finFET device having metal features formed using block type masks, in accordance with embodiments herein.

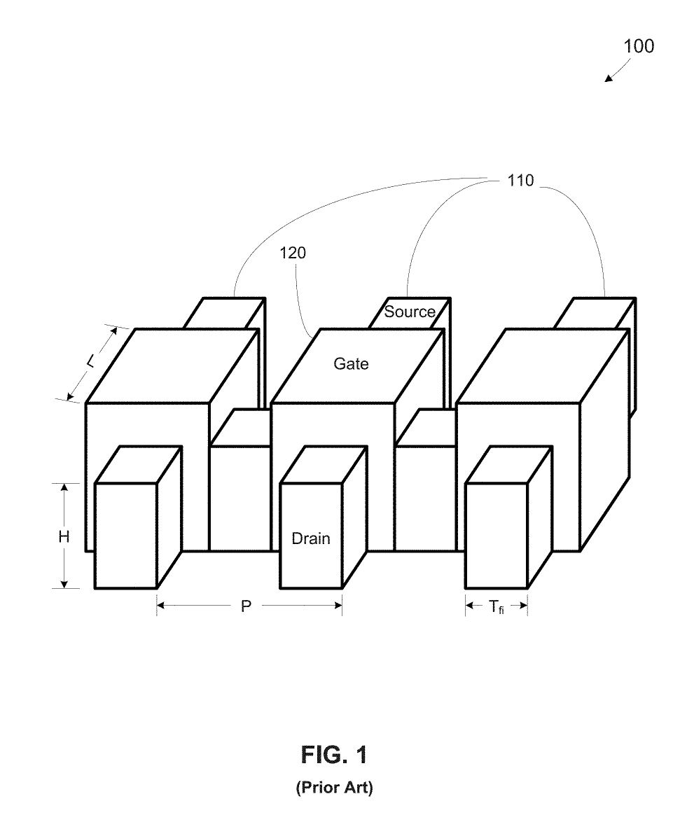

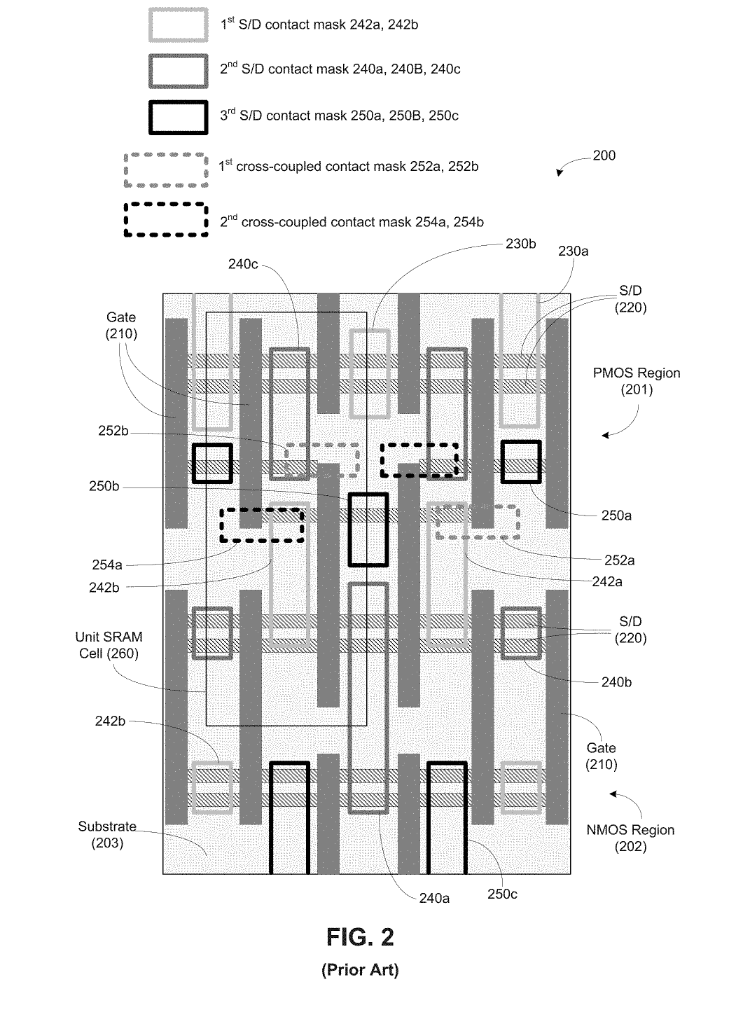

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached Figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Embodiments herein provide for forming contact structures in an integrated circuit (e.g., an SRAM device) using block-type self-aligned contact (SAC) pattern masks. In one embodiment, polysilicon (PC) gate-cut process may be performed prior to performing an RMG process, which may provide for forming nitride on a gate line, thereby making block-type SAC patterning possible. Embodiments herein provide for various advantages, such as increase of contact tip to tip margin, which provides for an increase in overlay and/or CD margins. Embodiments herein provide for a decrease in contact RIE aspect ratio, which provides for a reduction in nitride loss during processing of semiconductor wafers.

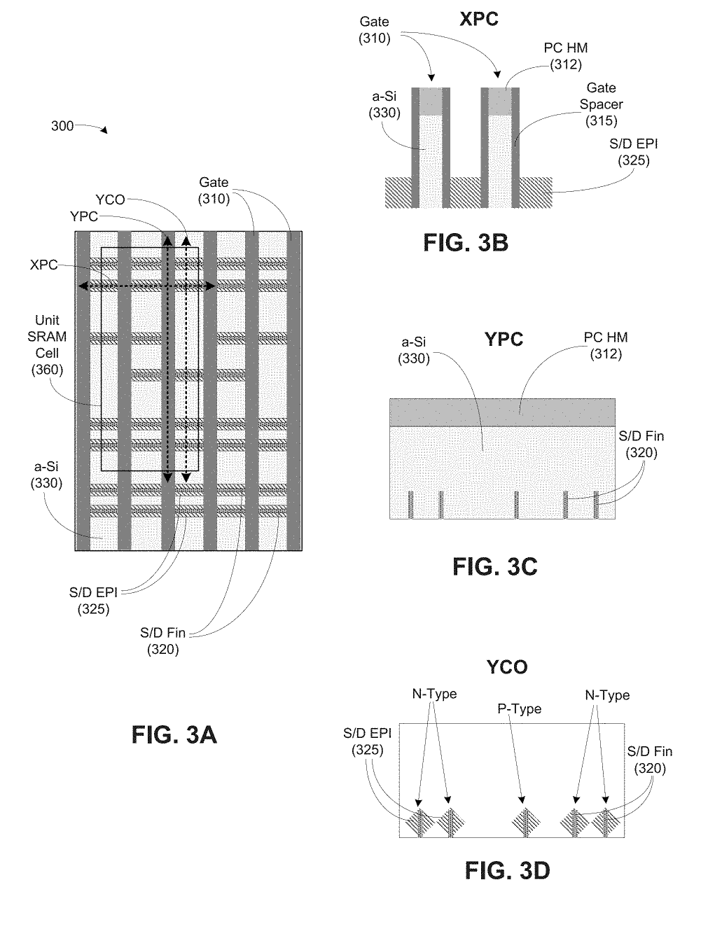

FIGS. 3-22 illustrate various stylized depictions of an integrated circuit with regard to performing block-type SAC pattern mask processing for forming an integrated circuits (e.g., SRAM devices), in accordance with embodiments herein.

Turning now to FIGS. 3A-3D, stylized depictions of various cross-sectional views of an integrated circuit with regard to post fin, PC and S/D formation processes, in accordance with embodiments herein, are illustrated. An integrated circuit 300 is formed, wherein a plurality of gate formations 310 may be formed on a substrate layer (e.g., amorphous silicon) 330. Further, a plurality of source/drain (S/D) formations 320 are formed. A dotted box 360 may represent a unit cell 360 for an integrated circuit device (e.g., a unit SRAM cell). Three dotted lines (XPC, YPC, and YCO) are shown, wherein FIGS. 3B, 3C and 3D represent cross-section views respectively represented by XPC, YPC, and YCO.

Continuing referring to FIGS. 3A-3D, the integrated circuit 300 comprises a PC amorphous silicon portion 330 upon which a PC hard mask 312 is formed (see FIG. 3B, XPC view). A gate spacer 315 is formed around the PC portions 330, 312. Epitaxial (EPI) formations 325 are formed on the S/D fins 320.

FIG. 3C shows the YPC cross-sectional view, showing the PC hard mask 310 and the PC amorphous silicon portion 330. The S/D fins 320 are also shown in FIG. 3C. FIG. 3C shows the YPC cross-sectional view, showing the S/D EPI formations 325. FIG. 3D shows N-type and P-type S/D EPI formations 325.

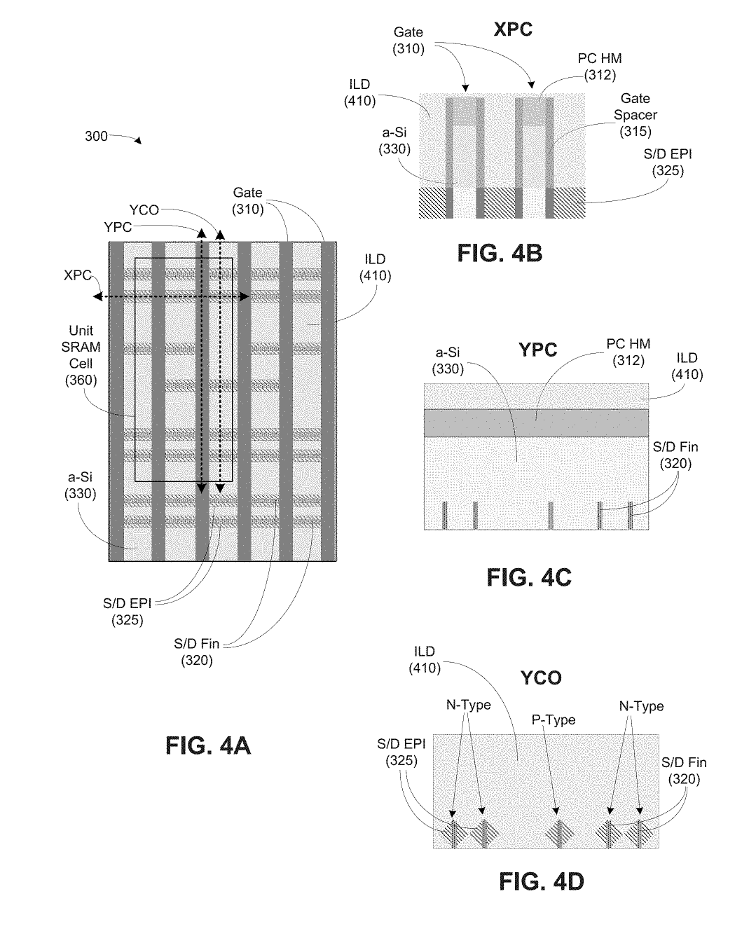

Turning now to FIGS. 4A-4D, stylized depictions of various cross-sectional views of an integrated circuit with regard to an ILD deposition process, in accordance with embodiments herein, are illustrated. An inter-layer dielectric (ILD) deposition process is performed for depositing an ILD layer 410. The ILD layer 410 may be comprised of one or more of many dielectric materials, such as an silicon oxide layer.

The ILD deposition process may be comprised of two process steps: a dielectric deposition process step; and an anneal process step, which in one embodiment, may be performed at a temperature in the range of about 500° C. to to about 600° C. FIG. 4B, 4C and 4D represent cross-section views respectively represented by XPC, YPC, and YCO. As shown in FIGS. 4B, 4C and 4D the ILD layer 410 is formed above S/D formations 320, and encompasses the PC formations 310.

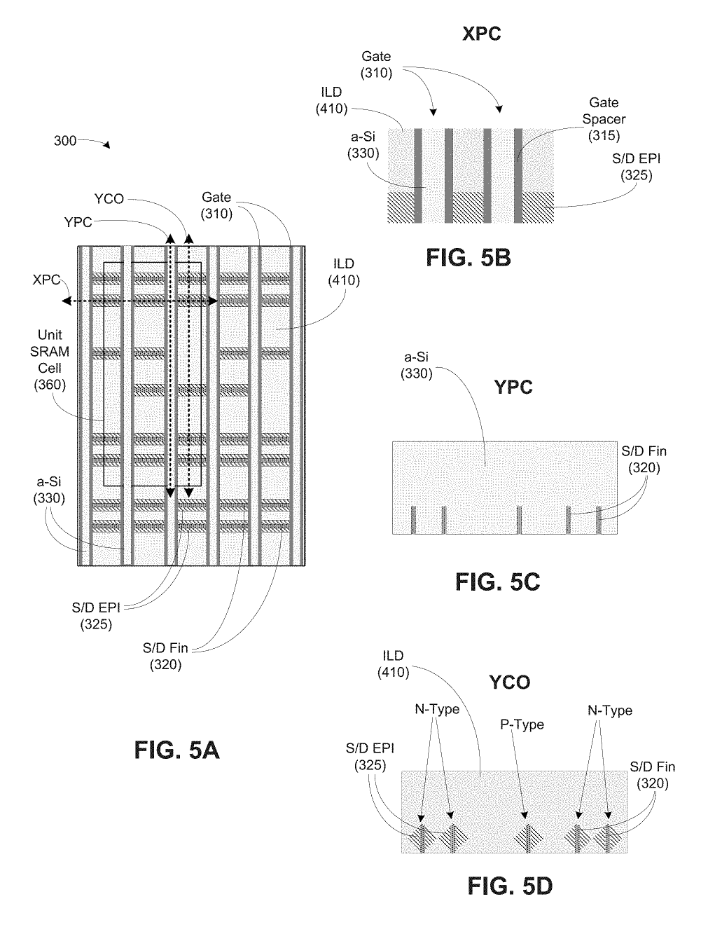

Turning now to FIGS. 5A-5D, stylized depictions of various cross-sectional views of an integrated circuit with regard to ILD CMP/Poly Open CMP processes, in accordance with embodiments herein, are illustrated. A chemical-mechanical process (CMP) is performed to polish the ILD layer 410 down to a predetermined height. Further, a CMP process is performed on the PC hard mask layer 310 above the PC amorphous silicon (a-Si) portion 330 of the PC.

FIGS. 5B, 5C and 5D represent cross-section views respectively represented by XPC, YPC, and YCO lines. The ILD layer 410 and the PC hard mask layer 312 are polished down to the top of the height of the PC a-Si layer 330, as shown in FIG. 5B. FIG. 5C indicates that the ILD layer 410 is entirely removed above the PC a-Si portion 330 and FIG. 5D indicates that the ILD layer 410 has been polished down to a predetermined height.

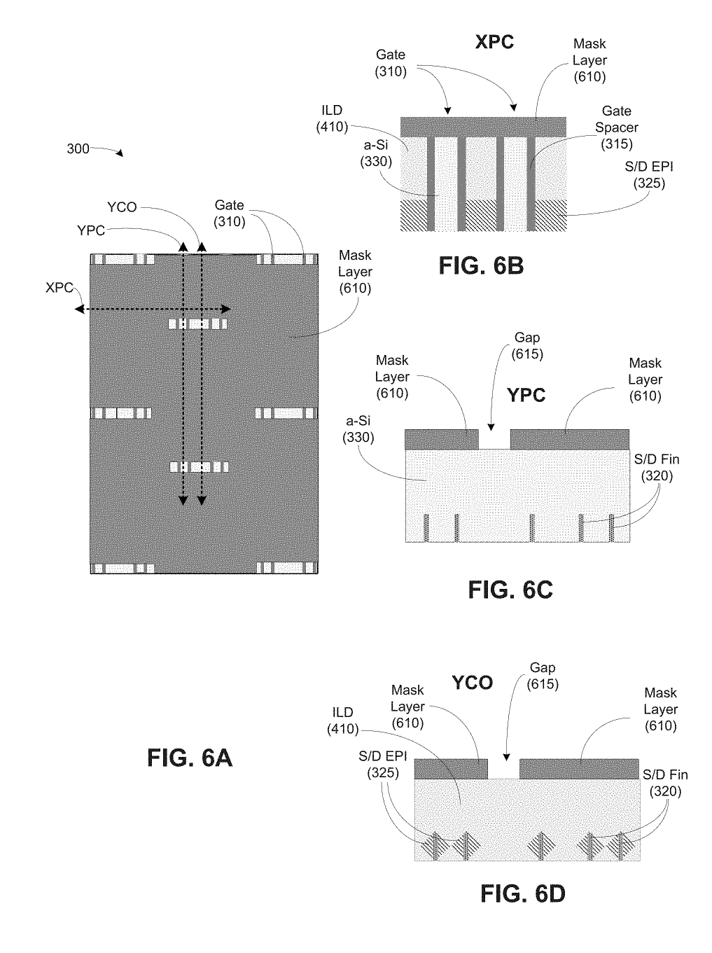

Turning now to FIGS. 6A-6D, stylized depictions of various cross-sectional views of an integrated circuit with regard to mask deposition and PC cut mask processes, in accordance with embodiments herein, are illustrated. A mask layer 610 is deposited for subsequently performing a PC cut mask process. Upon depositing the mask layer 610 a PC cut mask process is performed, selectively removing the mask as shown in FIGS. 6A-6D. The mask is cut-in for exposing portions of the gate formations at preselected locations, as shown in FIG. 6A.

FIGS. 6B, 6C and 6D represent cross-section views respectively represented by XPC, YPC, and YCO. The mask is cut in order to expose portions of the gate formations at preselected locations. FIG. 6B shows the mask layer 610 above the ILD layer. FIG. 6C shows the mask layer 610 above the PC a-Si 330. The gate cut results in a gap 615 in the mask layer 610 as shown in FIGS. 6C and 6D. Moreover, a silicon reactive ion etching (ME) process is performed to etch away the PC a-Si 330 portions beneath the gap 615, preserving the remainder of the PC a-Si layer 330.

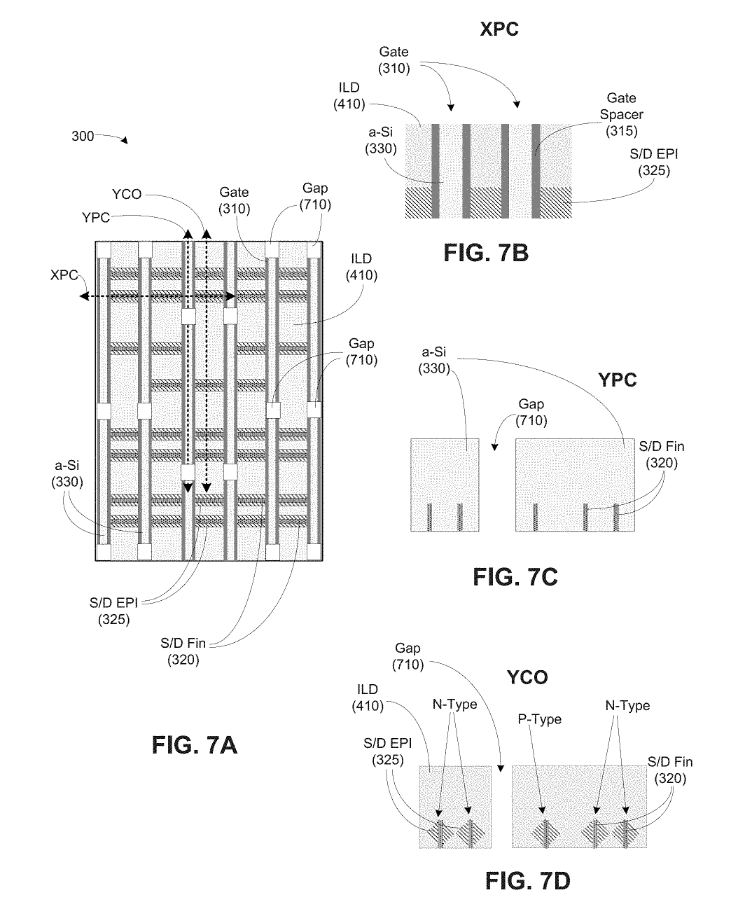

Turning now to FIGS. 7A-7D, stylized depictions of various cross-sectional views of an integrated circuit with regard to a PC cut RIE process, in accordance with embodiments herein, are illustrated. This process includes removing the mask layer 610 of FIG. 6A. The silicon ME process, in combination with the PC cut ME process, removes the mask layer 610 and the leaves gaps 710 in predetermined locations in the PC a-Si layer 330.

FIGS. 7B, 7C and 7D represent cross-section views respectively represented by XPC, YPC, and YCO. As shown in FIGS. 7B and 7D, the mask layer 610 has been removed. As shown in FIGS. 7C and 7D, the mask layer 610 is removed, leaving a gap 710 in the PC a-Si layer 330.

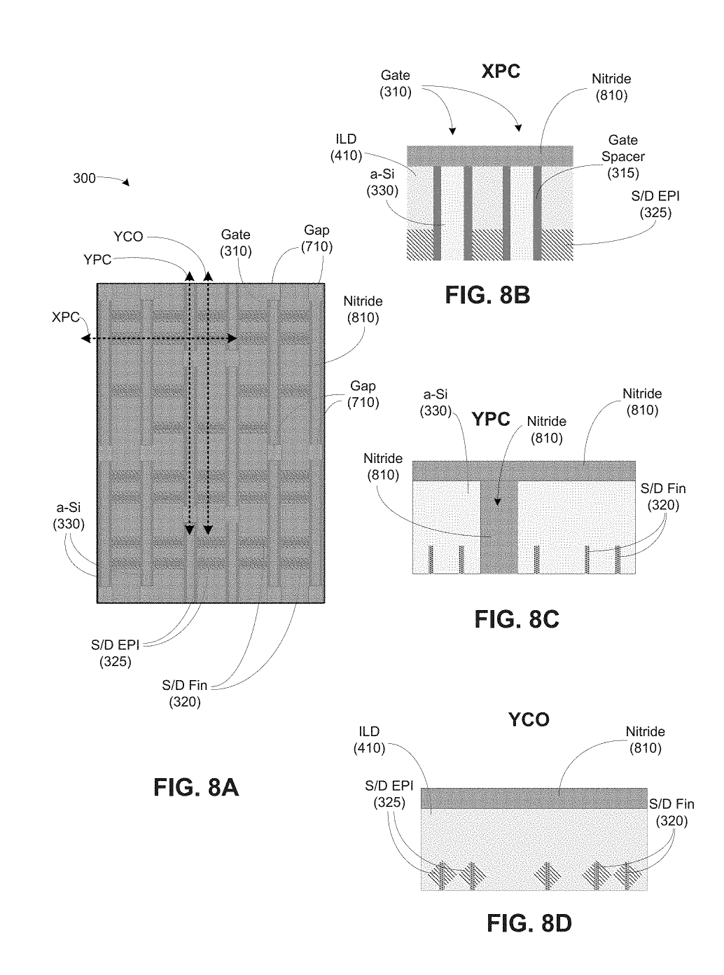

Turning now to FIGS. 8A-8D, stylized depictions of various cross-sectional views of an integrated circuit with regard to a PC cut nitride deposition process, in accordance with embodiments herein, are illustrated. A layer of silicon nitride 810 is deposited on the integrated circuit 200. The nitride material cover and enters into the gaps 710.

FIGS. 8B, 8C and 8D represent cross-section views respectively represented by XPC, YPC, and YCO. As shown in FIGS. 8B and 8D, the nitride layer 810 covers the ILD layer 410 and the PC a-Si layer 330. As shown in FIG. 8C, the nitride material 810 enters into the gap 710, filling the gap 710.

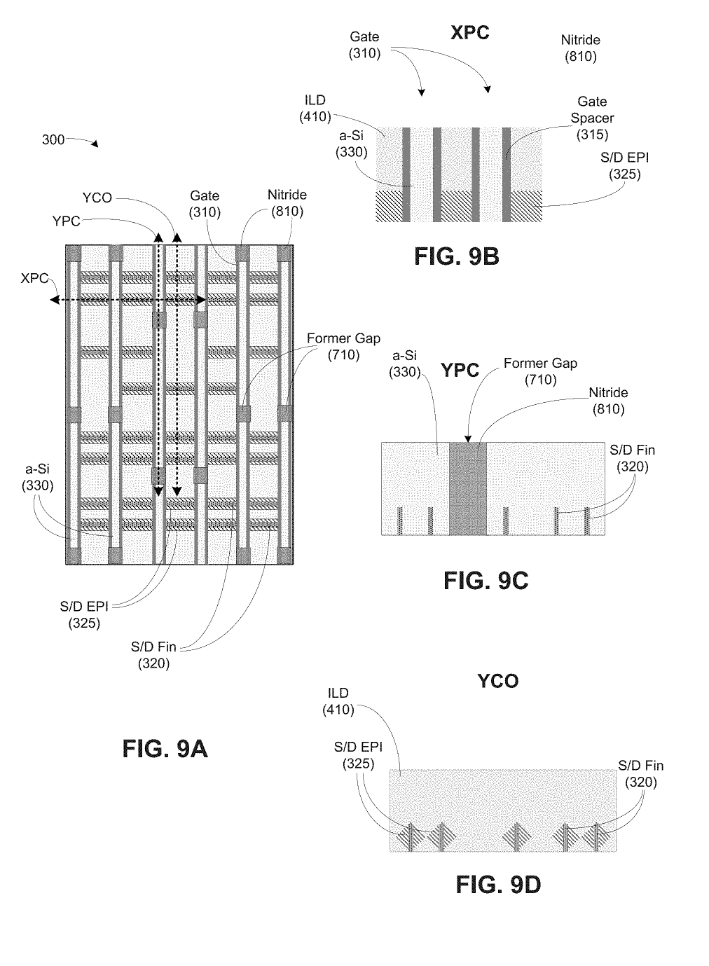

Turning now to FIGS. 9A-9D, stylized depictions of various cross-sectional views of an integrated circuit with regard to a PC cut nitride CMP process, in accordance with embodiments herein, are illustrated. A CMP process is performed to polish away the nitride layer 810 from the top portions of the ILD layer 410 and the gate structures 310. As such, the nitride material 810 remains in the gap 710.

FIGS. 9B, 9C and 9D represent cross-section views respectively represented by XPC, YPC, and YCO. As shown in FIGS. 9B and 9D, the nitride layer 810 is polished away. As shown in FIG. 9C, the nitride material 810 fills the gap 710.

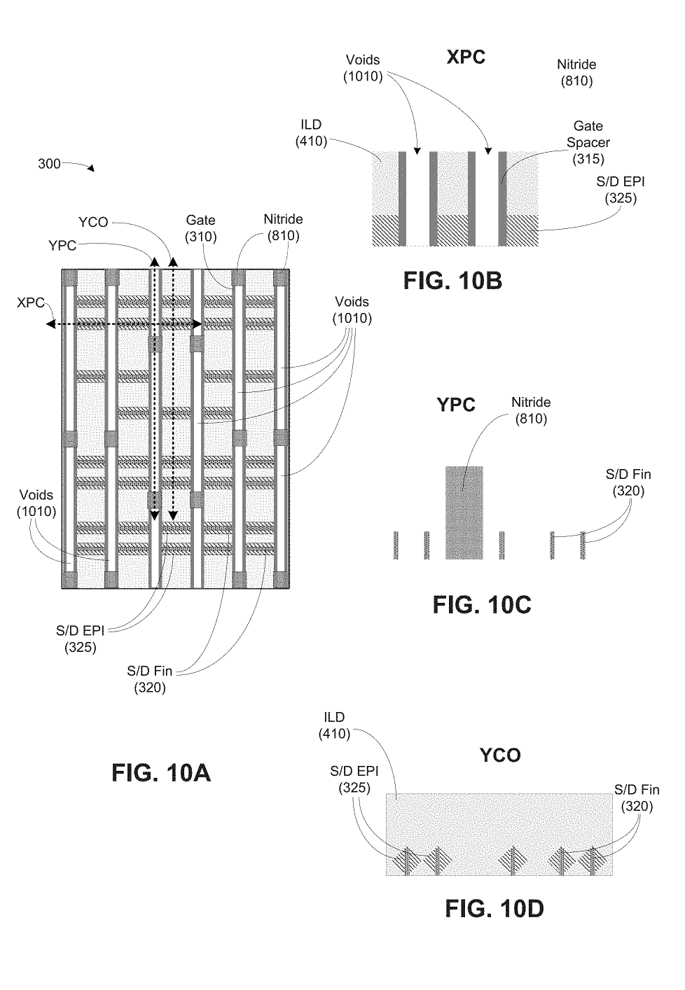

Turning now to FIGS. 10A-10D, stylized depictions of various cross-sectional views of an integrated circuit with regard to a poly pull process, in accordance with embodiments herein, are illustrated. A polly pull process is performed to remove the PC a-Si portions 330 of the gates structures 310. This leaves voids 1010 at the former locations of the PC a-Si portions 330.

FIGS. 10B, 10C and 10D represent cross-section views respectively represented by XPC, YPC, and YCO. As shown in FIG. 10B, voids 1010 exist where the PC a-Si portions 330 was present prior to the poly pull process. FIG. 10C shows a different view of the voids 810 left by the removal of the PC a-Si portions 330 of the gate structures 310.

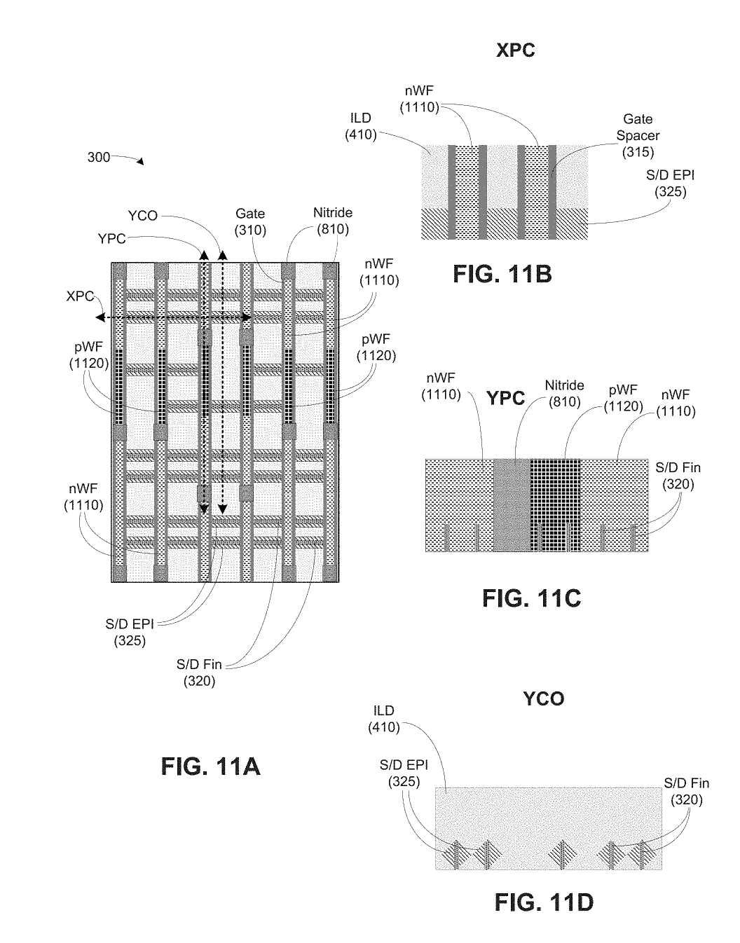

Turning now to FIGS. 11A-11D, stylized depictions of various cross-sectional views of an integrated circuit with regard to a replacement metal gate (RMG) process, in accordance with embodiments herein, are illustrated. In order to form gate structures 310, a metal material is deposited into the voids 1010 of FIG. 10, as shown in FIG. 11A. P-type and N-type metal materials are selectively added to form NMOS and PMOS gates. In some of the voids 1010, N-type work function metal material (nWF) 1110 is deposited, while in other voids 1010, P-type work function metal material (pWF) 1120 is deposited.

FIGS. 11B, 11C and 11D represent cross-section views respectively represented by XPC, YPC, and YCO. In the XPC cross-section view (FIG. 11B), nWF metal 1110 in the gate portion, between the gate spacers 315 are shown. In the YPC cross-sectional view (FIG. 11C), the gate portion 310 comprising the pWF metal 1120 is shown adjacent to the nitride layer 810 and two gate regions of nWF metal 1110 regions.

Further steps may be involved in the RMG process of FIG. 11A-D. For example, a hi-K cleaning process, a hi-K deposition process, a thin metal layer deposition process, and a tungsten deposition process may be performed as part of the RMG process.

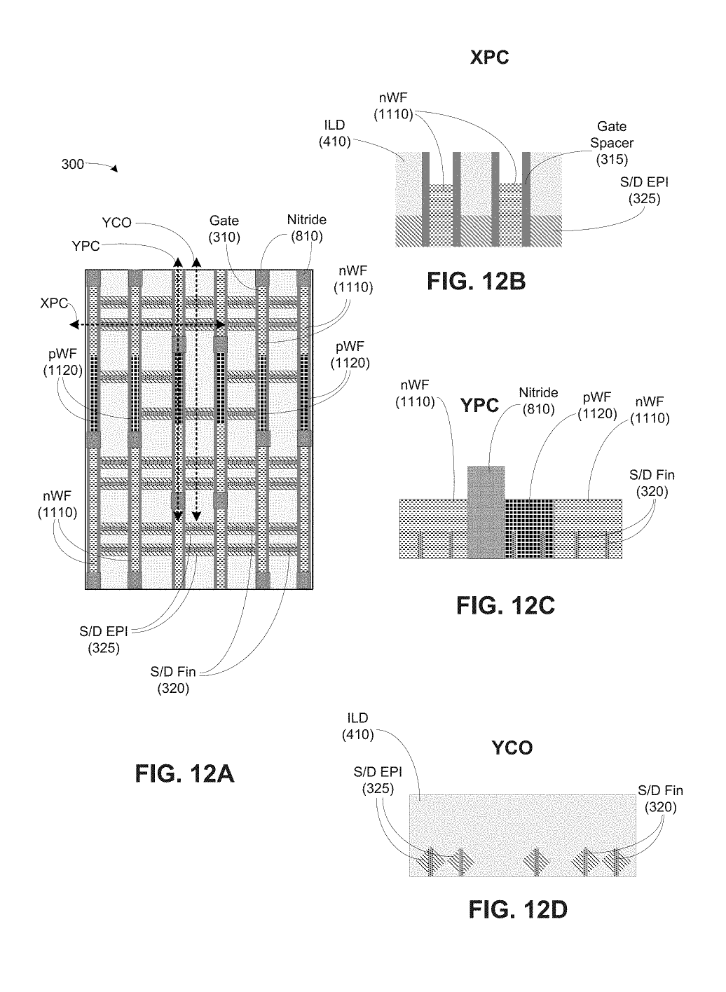

Turning now to FIGS. 12A-12D, stylized depictions of various cross-sectional views of an integrated circuit with regard to a RMG metal recess process, in accordance with embodiments herein, are illustrated. A recess process is performed to remove a portion of the RMG metal materials (i.e., nWF 1110, pWF 1120, tungsten) to a predetermined height. This process is performed to readying the integrated circuit 300 for deposition of a nitride hard mask layer.

FIGS. 12B, 12C and 12D represent cross-section views respectively represented by XPC, YPC, and YCO. The RMG metal materials (nWF 1110, pWF 1120, tungsten) are recessed to a predetermined depth below the nitride layer 810. As shown in FIG. 12B, the nWF layers 1110 are recessed to a predetermined height lower than the ILD layer 410. As shown in FIG. 12C, the The RMG metal materials (nWF 1110, pWF 1120) are recessed below the nitride layer 810.

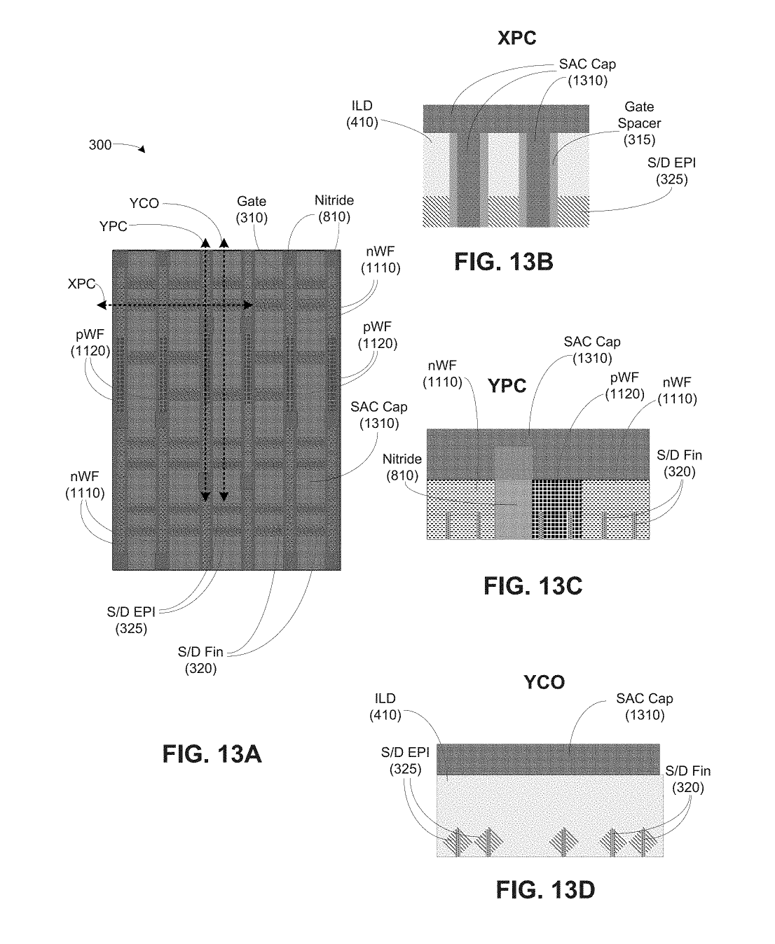

Turning now to FIGS. 13A-13D, stylized depictions of various cross-sectional views of an integrated circuit with regard to a RMG metal recess process, in accordance with embodiments herein, are illustrated. A SAC nitride cap layer 1310 is deposited on the integrated circuit 300.

FIGS. 13B, 13C and 13D represent cross-section views respectively represented by XPC, YPC, and YCO. As shown in FIG. 13B the nitride SAC cap layer 1310 is deposited above the nWF layers 1110, and flows into the recess area (FIG. 12B) between the gate spacers 315. FIGS. 13C shows the SAC cap layer 130 above the nWF 1110 and pWF layers 1120. FIG. 13D shows the SAC cap layer 1310 above the ILD layer 410.

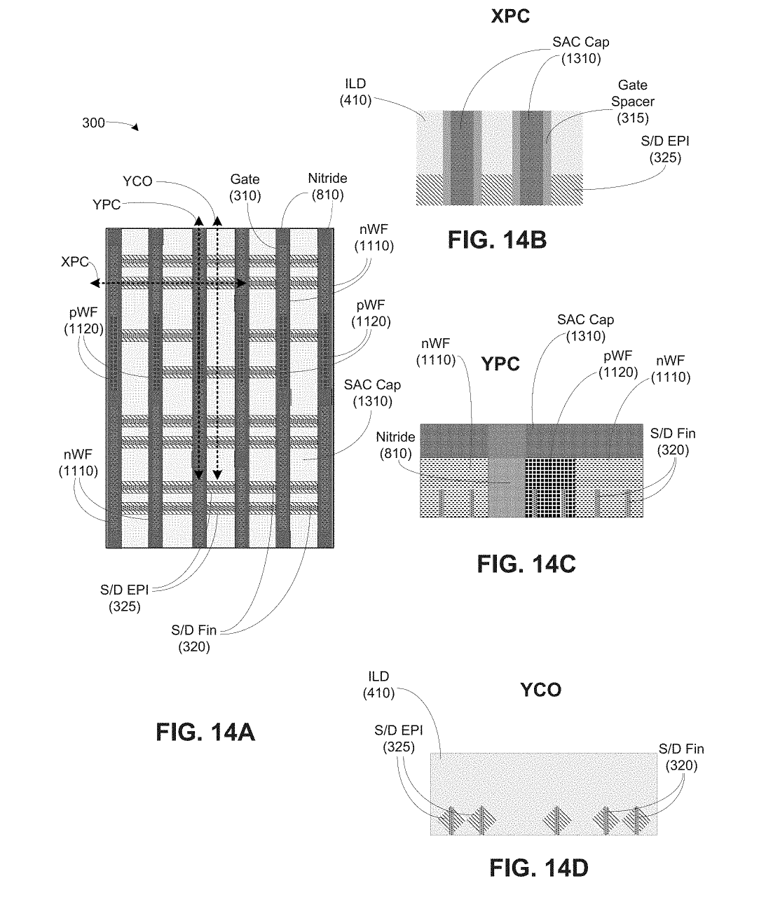

Turning now to FIGS. 14A-14D, stylized depictions of various cross-sectional views of an integrated circuit with regard to a RMG SAC nitridce CMP process, in accordance with embodiments herein, are illustrated. A CMP process is performed on the SAC nitride layer 1310.

FIGS. 14B, 14C and 14D represent cross-section views respectively represented by XPC, YPC, and YCO. As shown in FIG. 14B, the SAC cap layer 1310 is polished down to the height of the ILD layer 410. As shown in FIG. 14C, the SAC cap layer 1310 is polished down to the height of the nitride layer 810.

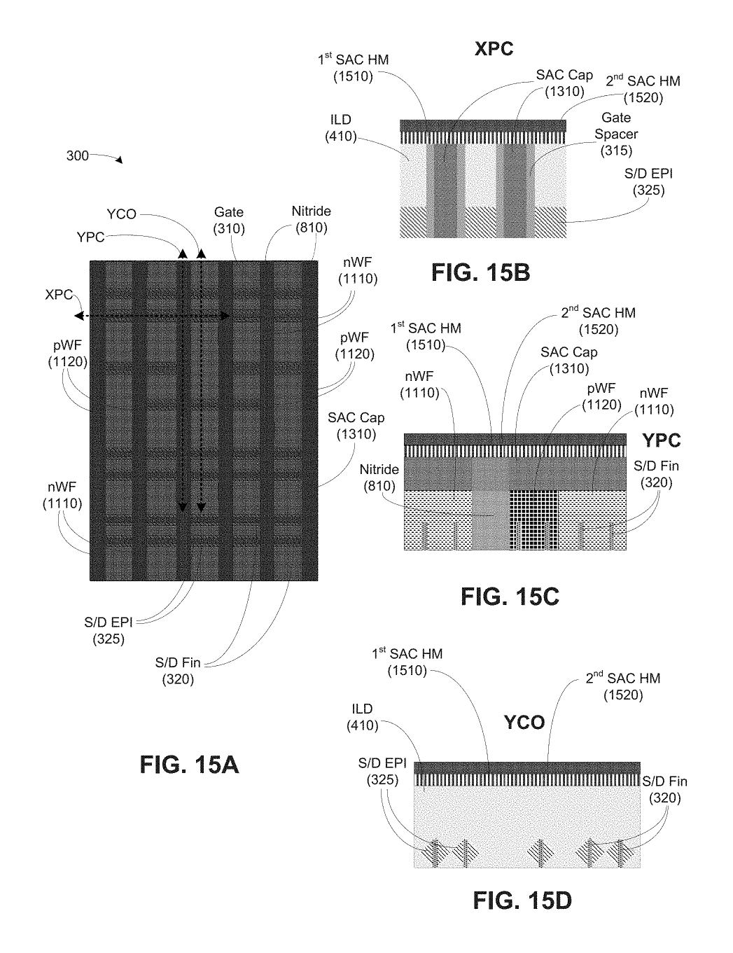

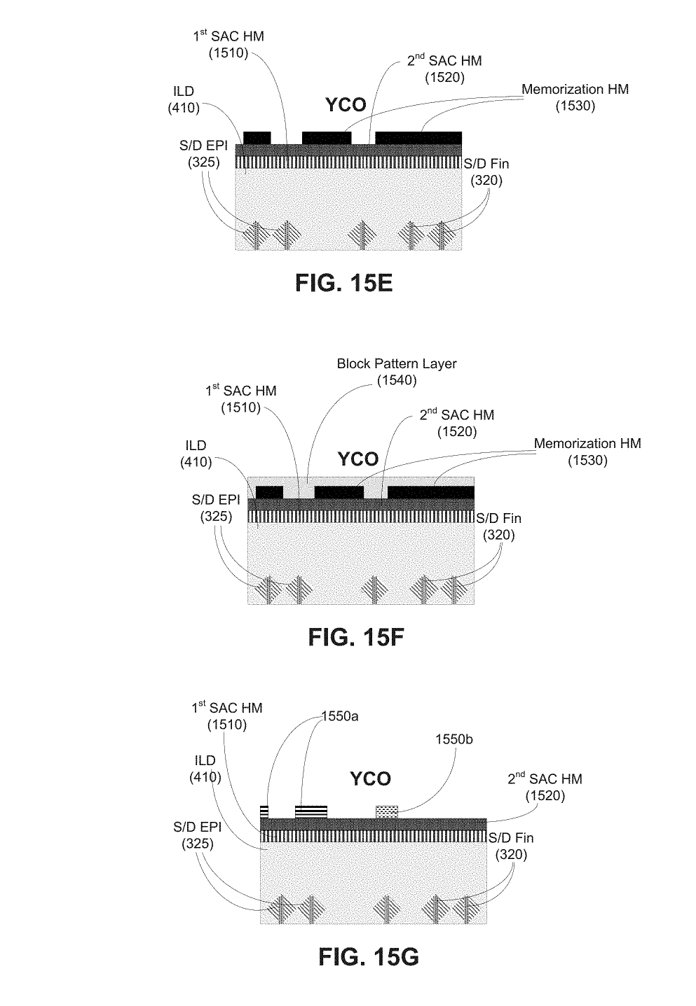

Turning now to FIGS. 15A-15G, stylized depictions of various cross-sectional views of an integrated circuit with regard to a SAC hard mask (HM) process, in accordance with embodiments herein, are illustrated. This process comprises depositing two hard mask layers. A 1^{st} HM layer 1510 is deposited, and a 2^{nd} HM layer 1520 is deposited on top of the 1^{st} HM layer 1510. In one embodiment, the 1^{st} HM layer 1510 may be an silicon oxide layer, and the 2^{nd} HM layer 1520 may be an silicon nitride layer. Both, the 1^{st} and 2^{nd} HM layers 1510, 1520 may be thin layers.

FIGS. 15B, 15C and 15D represent cross-section views respectively represented by the XPC, YPC, and YCO lines. Further, FIGS. 15E, 15F, and 15G represent additional cross-sectional views represented by the YPC line. As shown in FIG. 15B, the 1^{st} and 2^{nd} HM layers 1510, 1520 are deposited above the SAC cap layer 1310 fill, and above the ILD layer 410. As shown in FIG. 15C, the 1^{st} and 2^{nd} HM layers 1510, 1520 are deposited above the SAC cap layer 1310 and the nitride layer 810. FIG. 15D shows that the 1^{st} and 2^{nd} HM layers 1510, 1520 are deposited above the ILD layer 810.

As shown in FIG. 15E, a memorization HM layer 1530 is selectively deposited above the 2^{nd} HM layer 1520. In one embodiment, the memorization HM layer 1530 is deposited in such a manner that three different colors of trench type patterns may be fabricated. Further, as shown in FIG. 15D, a material for a block pattern layer 1540 is deposited above the memorization HM layer 1530 and the 2^{nd} HM layer 1520. Examples of the material for a block pattern layer 1540 may be carbon, silicon, or silicon oxide. The memorization HM layer 1530 comprises a plurality of predetermined voids for forming block masks. A CMP process may then be performed on the block pattern material. Subsequently, a plurality of SAC masks of a 1^{st}, 2^{nd} and 3^{rd} color (respectively 1550a, 1550b, 1550c) may be formed in the gaps in the memorization layer 1530, as shown in FIG. 15G. This process may be used to fabricate contact type patterns as well as stack type patterns.

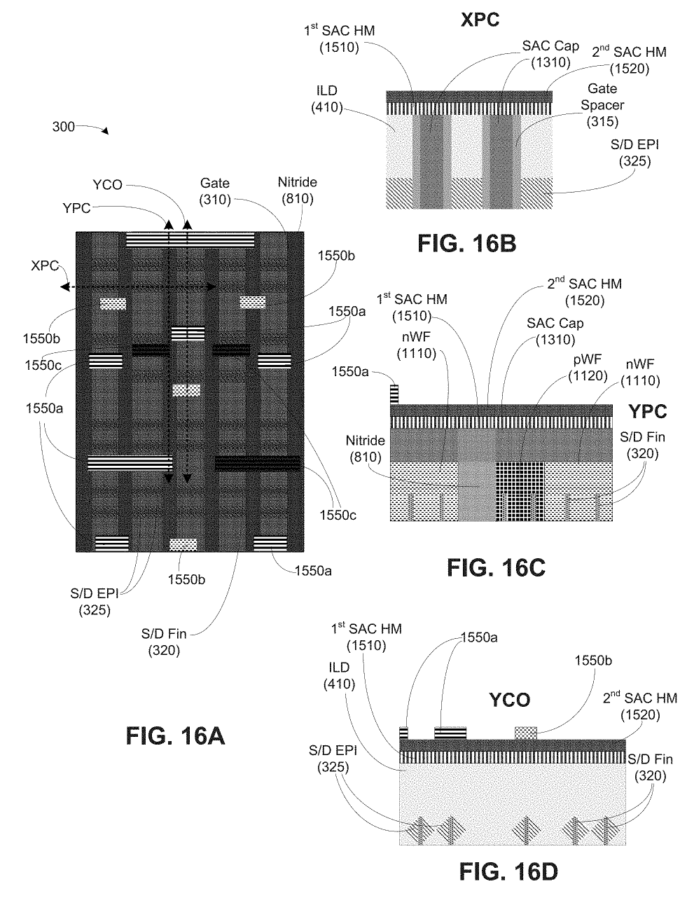

Turning now to FIGS. 16A-16D, stylized depictions of various cross-sectional views of an integrated circuit with regard to the SAC block type mask process described above, in accordance with embodiments herein, are illustrated. FIG. 16A shows a plurality of SAC masks of a 1^{st} color 1550a, a 2^{nd} color 1550b, and a 3^{rd} color 1550c. Those skilled in the art having benefit of the present disclosure would appreciate that although the SAC masks 1550a, 1550b, 1550c are shown as rectangles with right angle edges, in some embodiments, they may be rectangles or other polygons with rounded edges.

FIGS. 16B, 16C and 16D represent cross-section views respectively represented by XPC, YPC, and YCO. FIG. 16C shows one of the 1^{st} color block mask 1550a. FIG. 16D shows the 1^{st} color block masks 1550a and a 2^{nd} color block mask 1550b.

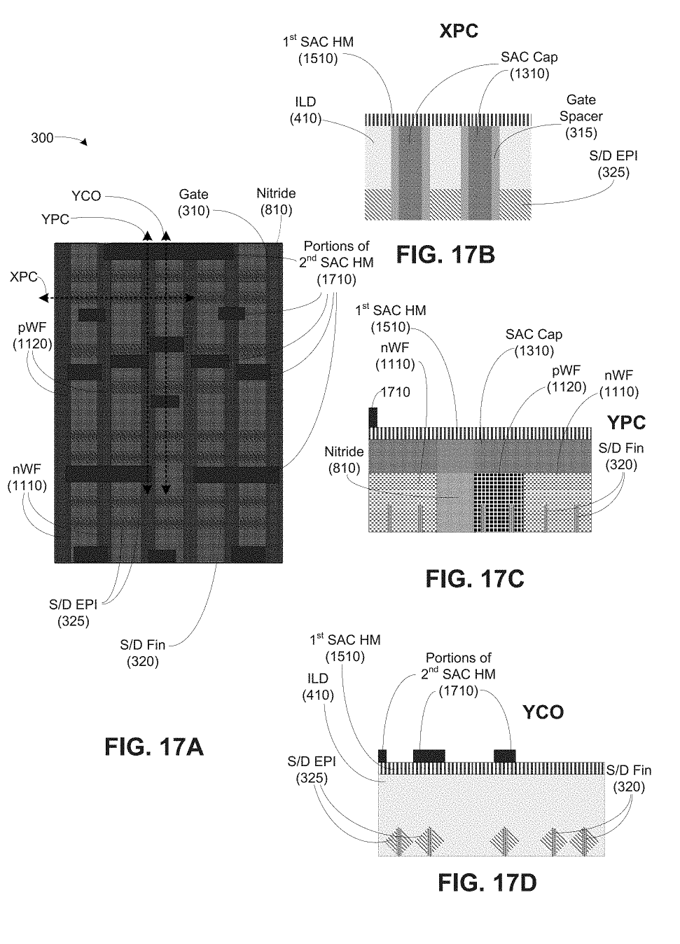

Turning now to FIGS. 17A-17D, stylized depictions of various cross-sectional views of an integrated circuit with regard to a SAC HM RIE process, in accordance with embodiments herein, are illustrated. A reactive ion etching (RIE) process may be performed to selectively etch portions of the 2^{nd} HM layer 1520. The block masks (1550a, 1550b, 1550c) are used to selectively etch away the 2^{nd} HM layer 1520, leaving behind the 1^{st} HM layer 1520. A plurality of 2^{nd} HM SAC pattern caps 1710 that were protected by the block masks (1550a, 1550b, 1550c) remain.

FIGS. 17B, 17C and 17D represent cross-section views respectively represented by XPC, YPC, and YCO. FIGS. 17C and 17D show the remaining portions of the 2^{nd} HM layer (1710) after performing the SAC HM RIE process. The portions of the 2^{nd} HM layer (1710) that are not protected by the block masks (1550a, 1550b, 1550c) are etched away, wherein the entirety of the 1^{st} HM layer 1510 remains. Once the block masks (1550a, 1550b, 1550c) are removed, the remaining portions of the 2^{nd} HM layer 1520 function as SAC pattern caps.

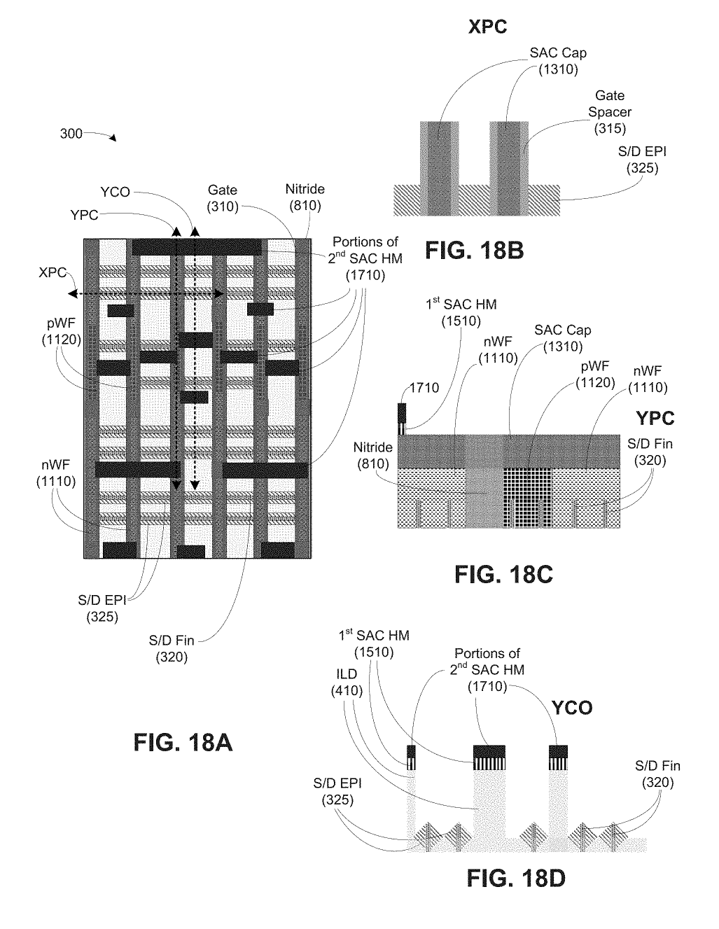

Turning now to FIGS. 18A-18D, stylized depictions of various cross-sectional views of an integrated circuit with regard to a SAC RIE process, in accordance with embodiments herein, are illustrated. FIG. 18A shows a plurality of 2^{nd} HM SAC pattern caps 1710 that were protected by the block masks (1550a, 1550b, 1550c). An SAC RIE process is performed to etch away material on the integrated circuit 300 that are not protected by the 2^{nd} HM SAC pattern caps 1810.

FIGS. 18B, 18C and 18D represent cross-section views respectively represented by XPC, YPC, and YCO. As shown in FIG. 18B, an oxide etch process is performed to etch away material down to the S/D EPI 325 structures. FIG. 18C shows an 2^{nd} HM SAC pattern cap 1810 that protects a portion of the 1^{st} HM SAC 1520. The SAC RIE process removes material down to the SAC CAP 1310 and the nitride layer 810. As shown in FIG. 18D, portions of the ILD material 410 that are not protected by the 2^{nd} HM SAC pattern caps 1810 are etched away, exposing the S/D EPI structures 325.

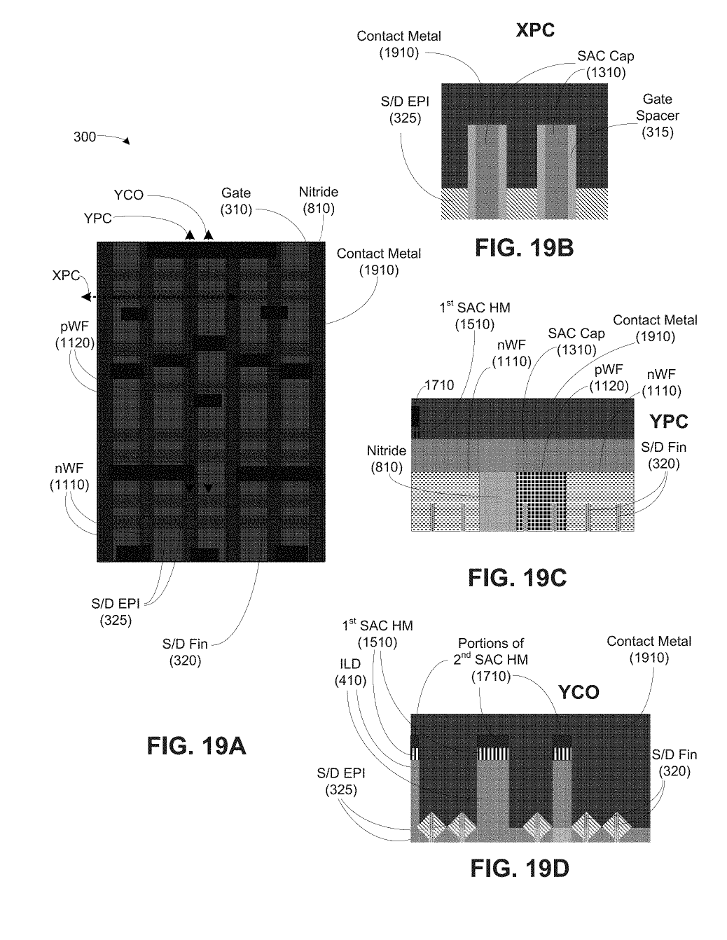

Turning now to FIGS. 19A-19D, stylized depictions of various cross-sectional views of an integrated circuit with regard to a contact metal deposition process, in accordance with embodiments herein, are illustrated. A contact metal deposition process is performed for depositing a contact metal 1910 (e.g., tungsten) over the integrated circuit 300 for form contact structures.

FIGS. 19B, 19C and 19D represent cross-section views respectively represented by XPC, YPC, and YCO. As shown in FIG. 19B, the contact metal 1910 is formed above and surrounding the gate spacer 315, down to the S/D EPI 325 structures. As shown in FIG. 19C, the contact metal is formed above the SAC cap layer 1310 and the nitride layer 810. Also, as shown in FIG. 19D, the contact layer 1910 fills the regions around the ILD layer 410 that is protected by the the 2^{nd} HM SAC pattern caps 1810, down to the S/D EPI structures 325.

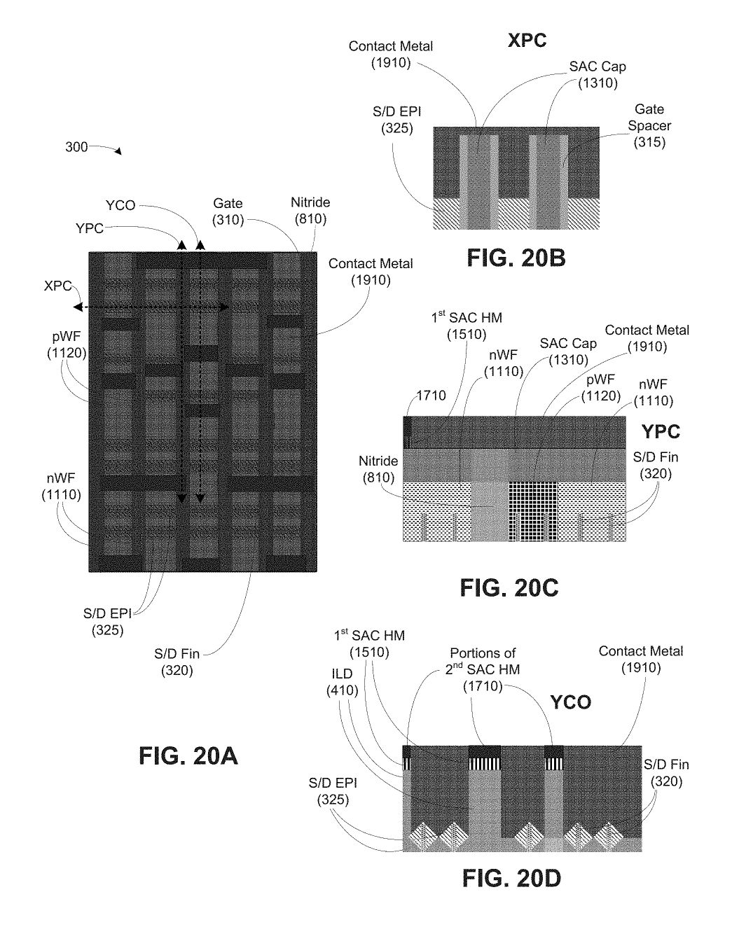

Turning now to FIGS. 20A-20D, stylized depictions of various cross-sectional views of an integrated circuit with regard to a contact metal CMP process described above, in accordance with embodiments herein, are illustrated. A CMP process is performed in the deposited contact metal layer 1910.

FIGS. 20B, 20C and 20D represent cross-section views respectively represented by XPC, YPC, and YCO. The contact metal layer 1910 is polished to just above the gate structure 310, as shown in FIG. 20B. Further, as shown in FIGS. 20C and 20D, the contact metal layer 1910 is polished to the level of the 2^{nd} HM SAC pattern caps 1810.

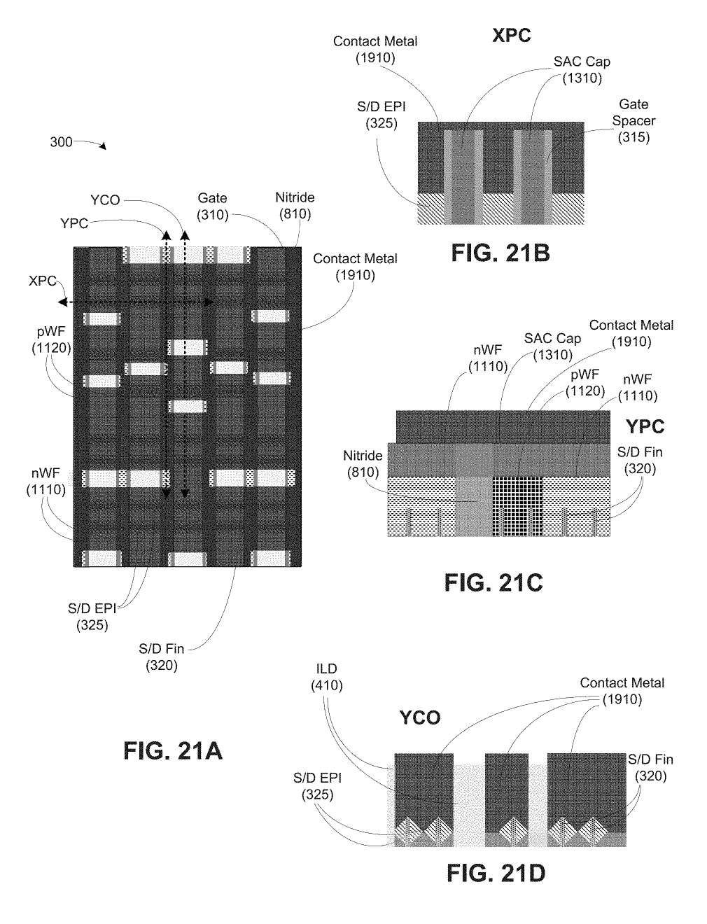

Turning now to FIGS. 21A-21D, stylized depictions of various cross-sectional views of an integrated circuit with regard to an SAC HM removal process, in accordance with embodiments herein, are illustrated. Once the contact metal layer 1910 is polished down to a predetermined level, a selective SAC HM removal process is performed for removing the contact metal layer 1910 is selective areas of the integrated circuit 300.

FIGS. 21B, 21C and 21D represent cross-section views respectively represented by XPC, YPC, and YCO. As shown in FIG. 21C, the 2^{nd} HM SAC pattern cap 1810 and the 1^{st} SAC HM layer 1510 from the region denoted by the circle 2110 is selectively etched away. As shown in FIG. 21D, the the 2^{nd} HM SAC pattern cap 1810 and the 1^{st} SAC HM layer 1510 from the areas denoted by the arrows 2120a, 2120b, 2120c are selectively etched away, leaving the contact metal regions 1910 in spaces between the ILD regions 410, and rising above to the height of the 2^{nd} HM SAC pattern caps 1810 and the 1^{st} SAC HM layers 1510.

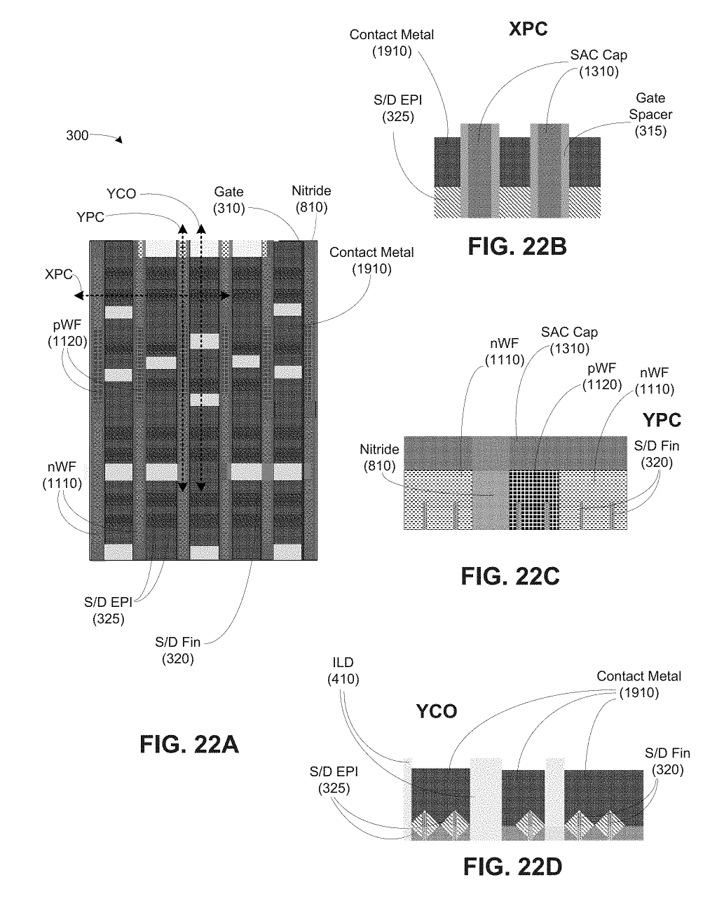

Turning now to FIGS. 22A-22D, stylized depictions of various cross-sectional views of an integrated circuit with regard to a contact metal etch-back process, in accordance with embodiments herein, are illustrated. Once the 2^{nd} HM SAC pattern caps 1810 and the 1^{st} SAC HM layers 1510 are removed, a contact metal etch back process is performed on the contact layer 1910 to form the final contact metal regions. This etch back process is performed such that the contact layer 1910 are etched back to a predetermined level below various structures, such as the gate structures 310 and the ILD layer 410.

FIGS. 22B, 22C, and 22D represent cross-section views respectively represented by XPC, YPC, and YCO. As shown in FIG. 22B, the contact layer 1910 are etched back to a predetermined level below the gate structures 310. As shown in FIG. 22C, the contact metal layer 1910 is completely removed above the gate structure 310, above the SAC cap layer 1310. As shown in FIG. 22D, the contact layer 1910 are etched back to a predetermined level below the ILD layers 410.

Accordingly, the contact structures 1910 formed herein is defined by the block type masks described above (see also FIGS. 16A-16D). The block type masks provides for separating the upper and lower contact metal regions, which helps avoid bridging. For example, as shown in FIG. 16A, some of the block masks (1550a, 1550b and 1550c) seperate the upper and lower metal regions. The formation of the contact metal features 1910 using the block type masks described herein provide for substantially reducing or eliminating bridging due to metal structures that are formed using different color masks.

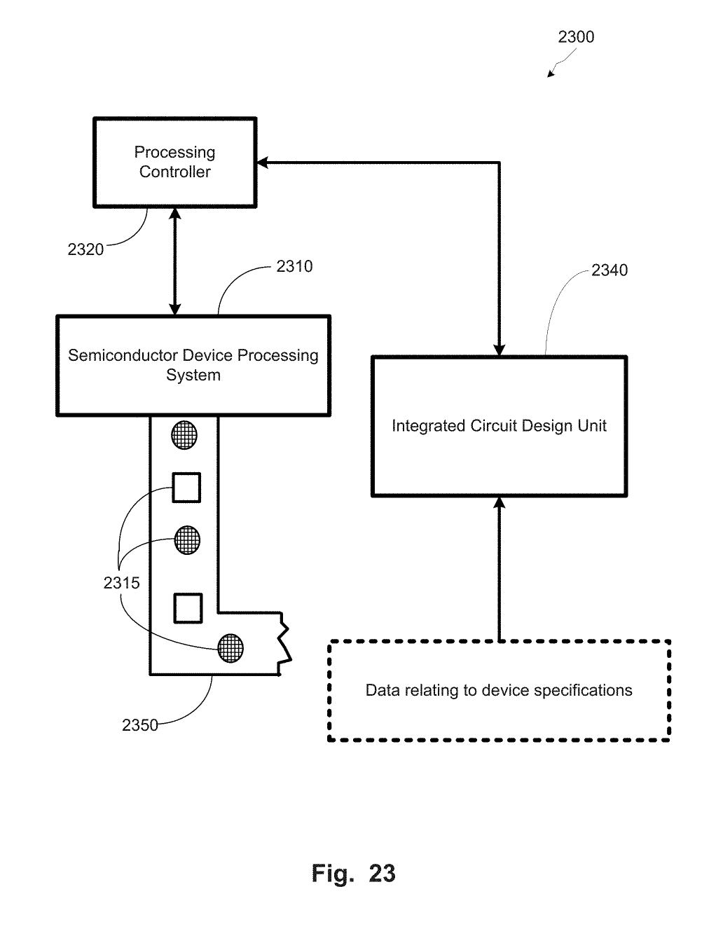

Turning now to FIG. 23, a stylized depiction of a system for fabricating a semiconductor device package comprising a finFET device having metal features formed using block type masks, in accordance with embodiments herein, is illustrated. The system 2300 of FIG. 23 may comprise a semiconductor device processing system 2310 and a design unit 2340. The semiconductor device processing system 2310 may manufacture integrated circuit devices based upon one or more designs provided by the design unit 2340.

The semiconductor device processing system 2310 may comprise various processing stations, such as etch process stations, photolithography process stations, CMP process stations, etc. One or more of the processing steps performed by the processing system 2310 may be controlled by the processing controller 2320. The processing controller 2320 may be a workstation computer, a desktop computer, a laptop computer, a tablet computer, or any other type of computing device comprising one or more software products that are capable of controlling processes, receiving process feedback, receiving test results data, performing learning cycle adjustments, performing process adjustments, etc.

The semiconductor device processing system 2310 may produce integrated circuits on a medium, such as silicon wafers. More particularly, the semiconductor device processing system 2310 produce integrated circuits having finFET devices that comprise metal features that are formed using block type masks, thereby avoiding bridging problems, as described above. The semiconductor device processing system 2310 is capable of performing the various process steps described in FIG. 3-22.

The production of integrated circuits by the device processing system 2310 may be based upon the circuit designs provided by the integrated circuits design unit 2340. The processing system 2310 may provide processed integrated circuits/devices 2315 on a transport mechanism 2350, such as a conveyor system. In some embodiments, the conveyor system may be sophisticated clean room transport systems that are capable of transporting semiconductor wafers. In one embodiment, the semiconductor device processing system 2310 may comprise a plurality of processing steps, e.g., the 1^{st} process step, the 2^{nd} process set, etc., as described above.

In some embodiments, the items labeled “2315” may represent individual wafers, and in other embodiments, the items 2315 may represent a group of semiconductor wafers, e.g., a “lot” of semiconductor wafers. The integrated circuit or device 2315 may be a transistor, a capacitor, a resistor, a memory cell, a processor, and/or the like. In one embodiment, the device 2315 is a transistor and the dielectric layer is a gate insulation layer for the transistor.

The integrated circuit design unit 2340 of the system 2300 is capable of providing a circuit design that may be manufactured by the semiconductor processing system 2310. The integrated circuit design unit 2340 may be capable of determining the number of devices (e.g., processors, memory devices, etc.) to place in a device package. The integrated circuit design unit 2340 may also determine the height of the gate fins, dimension of the S/D structures, the vias, the metal formations, etc., of the finFET devices. These dimensions may be based upon data relating to drive currents/performance metrics, device dimensions, etc. Based upon such details of the devices, the integrated circuit design unit 2340 may determine specifications (e.g., block mask processing specifications) of the finFETs that are to be manufactured. Based upon these specifications, the integrated circuit design unit 2340 may provide data for manufacturing a semiconductor device package described herein.

The system 2300 may be capable of performing analysis and manufacturing of various products involving various technologies. For example, the system 2300 may design and production data for manufacturing devices of CMOS technology, Flash technology, BiCMOS technology, power devices, memory devices (e.g., SRAM devices, DRAM devices), NAND memory devices, and/or various other semiconductor technologies.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed is:

1. A method, comprising:
forming a gate structure, a source structure, and a drain structure of a transistor, wherein said gate structure is surrounded by an inter-layer dielectric (ILD) region;
forming a first hard mask layer above said gate structure and said ILD region;
forming a second hard mask layer above said first hard mask layer;
forming a first block mask of a first color;
forming a second block mask of a second color;
etching selectively said first and second hard mask layers based on said first and second block mask layers for forming spaces for metal deposition;
performing a contact metal deposition process for forming a plurality of contact metal features;
removing said first and second hard mask layers; and
performing a third etch process for etching back the contact metal features to form contact metal structures.

2. The method of claim 1, wherein forming said gate structure comprises:
forming a gate structure;
forming EPI formations above said source and drain fins;
depositing a polysilicon (PC) hard mask layer over said gate structure;
depositing an inter-dielectric (ILD) layer above a plurality of EPI formations of said source drain structures;
performing an ILD chemical-mechanical polishing process on said ILD layer;
performing a PC hard mask layer CMP process for removing said PC hard mask layer;
performing a poly pull process for creating a plurality of voids for depositing gate metal;
depositing at least one of P-type work function (pWF) gate metal or N-type work function (nWF) into said voids; and
depositing a self-aligned cap layer above said gate structure.

3. The method of claim 1, wherein:
forming said first hard mask layer comprises forming a silicon oxide layer; and
forming said second hard mask layer above said first hard mask layer comprises forming a silicon nitride layer.

4. The method of claim 1, further comprising forming a memorization layer over said second hard mask layer, said memorization layer comprising a plurality of voids for forming said first and second block masks.

5. The method of claim 4, wherein said first block mask pattern is formed in a first set of voids of said plurality of voids, and wherein said second block pattern is formed in a second set of voids of said plurality of voids.

6. The method of claim 5, further comprising forming a third block mask pattern of a third color, wherein said third block mask pattern is formed in a third set of voids of said plurality of voids.

7. The method of claim 6, wherein said at least one of said first, second, and third block mask pattern is adapted to provide an isolation between a top portion of said gate structure integrated circuit and a bottom portion of said gate structure.

8. The method of claim 6, wherein further comprising performing a CMP process for removing said memorization layer.

9. The method of claim 7, wherein etching selectively said first and second hard mask layers comprises performing a first etch process comprising performing a first reactive ion etching process (ME) for removing portions of the second hard mask layer based on the patters of said first and second block masks.

10. The method of claim 8, wherein etching selectively said first and second hard mask layers comprising performing a second etch process comprising performing a second ME process for removing material that are not covered by said portions of said second hard mask layer, wherein said ILD layer portions that are not covered by said portion of said second hard mask layer are removed down a plurality of EPI formations of said source drain structures for forming a plurality of contact metal voids.

11. The method of claim 9, wherein performing said contact metal deposition process comprises:
depositing a contact metal material into said contact metal voids; and
performing a contact metal CMP process.

12. The method of claim 9, wherein:
removing said first and second hard mask layer comprises performing a hard mask selective etching process for selectively removing said first and second hard mask layers; and
performing said third etch process comprises performing a contact metal etch back process for etching down said contact metal down to a predetermined height below said ILD layer

13. A method, comprising:
providing an integrated circuit comprising a gate structure, a source structure, and a drain structure of a transistor, wherein said gate structure is surrounded by an inter-layer dielectric (ILD) region;
forming a first hard mask layer above said gate structure and said ILD region;
forming a second hard mask layer above said first hard mask layer;
forming a memorization layer comprising a plurality of voids for forming a plurality of block masks;
forming a first block mask of a first color in a first portion of said plurality of voids;
forming a second block mask of a second color in a first portion of said plurality of voids;
forming a third block mask of a third color in a first portion of said plurality of voids;
performing a first etch process for etching said second hard mask based on said first and second block masks;
performing a second etch process for etching said ILD region that is not covered by said second hard mask layer;
performing a contact metal deposition process for forming a plurality of contact metal features;
removing said first and second hard mask layers; and
performing a third etch process for etching back the contact metal features to form contact metal structures.

14. The method of claim 13, wherein performing said first etch process comprises performing a first reactive ion etching process (RIE) for removing portions of the second hard mask layer based on the patters of said first and second block masks.

15. The method of claim 14, wherein performing said second etch process comprises performing a second RIE process for removing material that are not covered by said portions of said second hard mask layer, wherein said ILD layer portions that are not covered by said portion of said second hard mask layer are removed down a plurality of EPI formations of said source drain structures for forming a plurality of contact metal voids.

16. The method of claim 15, wherein:
performing said contact metal deposition process comprises depositing a contact metal material into said contact metal voids; and performing a contact metal CMP process;
removing said first and second hard mask layers comprises performing a hard mask selective etching process for selectively removing said first and second hard mask layers;
performing said third etch process comprises performing a contact metal etch back process for etching down said contact metal down to a predetermined height below said ILD layer; and
wherein said integrated circuit is a memory device.

17. A system, comprising:
a semiconductor device processing system to manufacture a semiconductor device comprising at least one fin field effect transistor (finFET); and
a processing controller operatively coupled to said semiconductor device processing system, said processing controller configured to control an operation of said semiconductor device processing system;
wherein said semiconductor device processing system is adapted to:
form a gate structure, a source structure, and a drain structure of a transistor, wherein said gate structure is surrounded by an inter-layer dielectric (ILD) region;
form a first hard mask layer above said gate structure and said ILD region;
form a second hard mask layer above said first hard mask layer;
form a first block mask of a first color;
form a second block mask of a second color;
etch selectively said first and second hard mask layers based on said first and second block mask layers for forming spaces for metal deposition;
perform a contact metal deposition process for forming a plurality of contact metal features;
remove said first and second hard mask layers; and
perform a third etch process for etching back the contact metal features to form contact metal structures.

18. The system of claim 17, wherein said semiconductor device processing system is further adapted to selectively etch said first and second hard mask layers comprises performing a first etch process comprising performing a first reactive ion etching process (ME) for removing portions of the second hard mask layer based on the patters of said first and second block masks.

19. The system of claim 18, wherein said semiconductor device processing system is further adapted to selectively etch said first and second hard mask layers comprising performing a second etch process comprising performing a second ME process for removing material that are not covered by said portions of said second hard mask layer, wherein said ILD layer portions that are not covered by said portion of said second hard mask layer are removed down a plurality of EPI formations of said source drain structures for forming a plurality of contact metal voids.

20. The system of claim 19, wherein said semiconductor device processing system is further adapted to:
deposit a contact metal material into said contact metal voids; and perform a contact metal CMP process for performing said contact metal deposition process;
perform a hard mask selective etching process for selectively removing said first and second hard mask layers for removing said first and second hard mask layers; and
perform a contact metal etch back process for etching down said contact metal down to a predetermined height below said ILD layer for performing said third etch process.
